(19) United States
(12) Patent Application Publication
(10) Pub. No.: US 2003/0118948 A1
(43) Pub. Date: Jun. 26, 2003

(54) Method of etching semiconductor material to achieve structure suitable for optics

(76) Inventor: Rohit Grover, Greenbelt, MD (US)

Correspondence Address: OFFICE OF THE ASSOC. GEN. COUNSEL (IP & T), 9800 SAVAGE ROAD SUITE 6542, FORT MEADE, MD, 20755-6542, US

(21) Appl. No.: 10/323,182

(22) Filed: Dec. 18, 2002

Related U.S. Application Data
(60) Provisional application No. 60/342,908, filed on Dec. 21, 2001.

(51) Int. Cl. G03F 7/00

(52) U.S. Cl. 430/311; 430/313; 430/314

(57) ABSTRACT

A method of etching a semiconductor material by first selecting a substrate material. Next, patterning a mask layer onto the substrate. The substrate material over which the mask layer does not appear is then etched for a user-definable time. Any polymer that builds up on the sidewalls of the substrate material being etched is removed. If the substrate material has been etched and cleaned at least twice then stop. Otherwise, return to the substrate etch step for additional processing. The present invention performs a cleaning step to remove polymer that builds up on the sidewalls of the desired structure after etching only a portion of the desired depth of the resulting structure. Therefore, no polymer is allowed to build up and affect the verticality of the resulting structure.

This application claims the benefit of U.S. Provisional Application No. 60/342,908, filed Dec. 21, 2001.

### FIELD OF THE INVENTION

This invention relates to semiconductor device manufacturing process and, more particularly, to chemical etching by reactive ion beam etching.

### BACKGROUND OF THE INVENTION

Dry-etching, due to its unique capability for high-resolution pattern transfer, is an important process for fabricating semiconductor devices. Systems using group III-V semiconductor materials offer the possibility of active optical devices. In particular, materials based on indium phosphide (InP) may be used to make high-speed, long-wavelength components for use in optical systems.

Reactive ion etching (RIE) techniques have been developed specifically for InP-based materials. RIE utilizes radicals and ions of a low pressure plasma (5 . . . 100 mTorr) of chemically active gases. Etching by reactive species absorbed at the semiconductor surface is stimulated by ions accelerated through a voltage bias of 100 . . . 700V.

In an article entitled “Recent Advances in Dry-Etching Processes for InP-Based Materials,” Third International Conference, Indium Phosphide and Related Materials, 1991, U. Niggebrugge presents a survey of known RIE methods, none of which disclose the present invention.

In an article entitled “Process Development on the Monolithic Fabrication of an Ultra-compact 4×4 Optical Switch Matrix on InP/InGaAsP Material,” Conference Proceedings, Eleventh International Conference on Indium Phosphide and Related Materials (IPRM'99), 1999, Y. H. Qian et al. studied Titanium Silicon Nitride (TiSiN) bi-level masks and reported that Ti film tended to sputter during their process, but did not disclose the present invention.

In an article entitled “Anisotropy Control In The Reactive Ion Etching of InP Using Oxygen In Methane/Hydrogen/Argon,” Proceeding of 1994 IEEE 6^{th} International Conference on Indium Phosphide and Related Materials (IPRM), 1994, J. E. Schramm et al. contrasts the various uses of oxygen in methane/hydrogen/argon RIE to reduce the rate of polymer formation, but does not disclose the present invention.

In an article entitled “High rate CH₄:H₂ plasma etch processes for InP,” Journal of Vacuum Science & Technology B (Microelectronics and Nanometer Structures), 1997, C. S. Whelan disclose a method of achieving high etch rates, but does not disclose the present invention.

U.S. Pat. No. 5,624,529, entitled “DRY ETCHING METHOD FOR COMPOUND SEMICONDUCTORS,” discloses an dry etch method that uses a gaseous plasma of boron, trichloride, methane, and hydrogen. The present invention does not use such a gaseous plasma. U.S. Pat. No. 5,624,529 is hereby incorporated by reference into the specification of the present invention.

U.S. Pat. No. 6,063,699, entitled “METHODS FOR MAKING HIGH-ASPECT RATIO HOLES IN SEMICONDUCTOR AND ITS APPLICATION TO A GATE DAMASCENE PROCESS FOR SUB-0.05 MICRON MOSFETS,” discloses a method of using a sacrificial polysilicon layer. The present invention does not use a sacrificial polysilicon layer. U.S. Pat. No. 6,063,699 is hereby incorporated by reference into the specification of the present invention.

U.S. Pat. No. 6,410,213, entitled “METHOD FOR MAKING OPTICAL MICROSTRUCTURES HAVING PROFILE HEIGHTS EXCEEDING FIFTEEN MICRONS,” discloses a method of varying an exposure dose spatially based upon predetermined contrast curves of photosentitive material to achieve surface sags greater than 15 um in 1-D and 2-D surface contours. The present invention does not use such predetermined contrast curves of photosensitive material to achieve its objective. U.S. Pat. No. 6,410,213 is hereby incorporated by reference into the specification of the present invention.

Dry-etching of InP and related materials has been studied extensively. However, the prior art methods do not result in deep optical quality sidewalls/facets with high verticality as does the present invention.

### SUMMARY OF THE INVENTION

It is an object of the present invention to dry-etch semiconductor material to achieve sidewalls that are useful in optics.

It is another object of the present invention to dry-etch semiconductor material to achieve sidewalls that are useful in optics with verticality of at least 89 degrees.

It is another object of the present invention to dry-etch semiconductor material to achieve sidewalls that are useful in optics with verticality of at least 89 degrees by employing TiSiO₂ bi-level mask and a user-definable number of cleaning steps to remove unwanted polymer that builds up on the sidewalls.

The present invention is a method of dry-etching a semiconductor material to achieve sidewalls that are useful in optical devices with verticality of at least 89 degrees.

The first step of the method is selecting a substrate of a user-definable semiconductor material.

The second step is patterning a mask layer onto the substrate.

The third step of the method is etching the result of the second step for a user-definable time.

The fourth step of the method is cleaning polymer that built up on the sidewalls of the result of the third step for a user-definable time.

If the third and fourth steps of the method were performed at least twice, stop. Otherwise return to the third step for additional processing.

### BRIEF DESCRIPTION OF THE DRAWINGS

FIG. 1 is a flowchart of the etch method of the present invention.

### DETAILED DESCRIPTION

The present invention is a method of etching a semiconductor material to achieve sidewalls that are useful in optical devices with verticality of at least 89 degrees. To be useful for optics, the device must have a smoothness of less than 50 nm. Devices made by the present invention may achieve a smoothness of less than or equal to 10 nm.

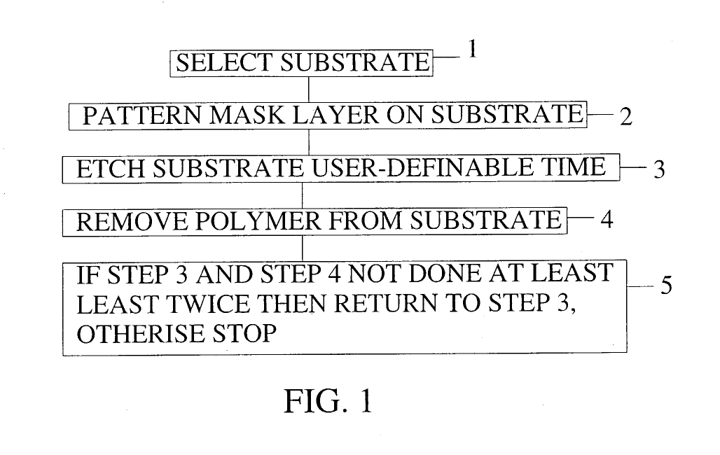

FIG. 1 is a flowchart of the etch method of the present invention.

The first step 1 of the method is selecting a substrate of a user-definable semiconductor material. In the preferred embodiment, an InP substrate is selected because such a substrate may be used to fabricate active optical devices that operate at a wavelength of 1550 nm such as MEMS, photonic wires, and photonic crystals. However, any other semiconductor material, especially one from Group III-V is possible.

The second step 2 of the method is patterning a mask layer onto the substrate. The mask layer may be patterned by an etching process, a lift-off process, or a combination of the ecth process and the lift-off process.

In an etch process for patterning a mask layer, a mask layer is deposited onto the substrate. The mask layer may be Titanium-silicon-dioxide (TiSiO₂), Titanium (Ti), Silicon-Dioxide (SiO₂), Silicon-Nitride (Si₃N₄), or any other suitable mask layer. A bi-level mask such as TiSiO₂ eliminates mask erosion and results in sidewalls that are sufficiently smooth to be used in optical devices. In the preferred embodiment, the TiSiO₂ mask layer is made by depositing 500 nm of SiO₂ onto the substrate material and then depositing 500 nm of Ti on the SiO₂. Next, a resist layer is deposited onto the mask layer in a user-definable pattern. The resist may be either positive resist or negative resist. If positive resist is used, the resist is deposited in a pattern that is to be the resulting pattern of the mask layer. If negative resist is used, the resist is deposited in a pattern that represents the areas of the deposited mask layer that is to be removed. The resist may be of a type that is cured by any suitable means (e.g., photoresist, E-beam resist). If positive resist is used, the areas of the mask layer over which resist does not appear is etched away. In the preferred embodiment RIE is used to etch away areas of the mask layer over which no resist appears. The chemistry used in the RIE may be hydrogen (H₂), methane (CH₄), Argon (Ar), Oxygen (O₂), Trifluoromethane (CHF₃), Sulfur-hexafluoride (SF₆), any suitable combination thereof, and any other suitable chemistry. In a first preferred embodiment, CH₄—H₂—Ar is used to etch the areas of the mask layer. In the preferred embodiment, CH₄—H₂—Ar is used to etch the areas of the mask layer. Any resist that remains on top of the resulting mask pattern is removed.

In a lift-off process for patterning a mask layer, a resist layer is deposited onto the substrate. The resist layer may be as described above. Next, the resist layer is patterned. The resist may be patterned as described above. Next, a mask layer is deposited onto the combination of substrate and patterned resist. The mask layer may be Nickel (Ni), Chromium (Cr), Nicrome (NiCr), or any other suitable mask layer. Next, the patterned resist layer is dissolved. The resist is dissolved using any suitable dissolving method.

In a combination of etch and lift-off method of patterning a mask layer, a first mask layer is deposited onto the substrate. Next, a resist, as described above, is deposited onto the first mask layer. Next, the resist is patterned. Next, a second mask layer is deposited onto the combination of substrate, first mask layer, and patterned resist. Next, the patterned resist is dissolved. Next, the first mask layer is etched.

The third step 3 of the method is etching the substrate material over which the mask layer does not appear for a user-definable time. In the preferred embodiment RIE is used to etch away areas of the mask layer over which no resist appears. The chemistry used in the RIE may be hydrogen (H₂), methane (CH₄), Argon (Ar), Oxygen (O₂), Trifluoromethane (CHF₃), Sulfur-hexafluoride (SF₆), any suitable combination thereof, and any other suitable chemistry. In the preferred embodiment, CH₄—H₂—Ar is used to etch the substrate material. In the preferred embodiment, the third step 3 is performed for 5 minutes.

The fourth step 4 of the method is to clean polymer that built up on the sidewalls/facets of the substrate material under the mask layer during the last step for a user-definable time. In the preferred embodiment, hydrofluoric acid is used to clean polymer that has built up on the sidewalls of the substrate material. In the preferred embodiment, the fourth step 4 is performed for 3 minutes. The hydrofluoric acid may be buffered or unbuffered. In an alternate embodiment, O₂ may be used to reduce polymer buildup. It has been reported that the addition of O₂ reduces the buildup of polymer on the sidewalls/facets of the substrate material as it is being etched in the following step. Polymer buildup is a major problem to obtaining optical quality sidewalls/facets and achieving sidewall/facet verticality of at least 89 degrees.

If the third step 3 and the fourth step 4 of the method were each performed at least twice, stop. Otherwise return to the third step 3 for additional processing. In the preferred embodiment, the third step 3 and the fourth step 4 were each performed 50 times before stopping.

The present invention doesn't attempt to etch the entire depth of the desired structure and then attempt to remove the polymer that has built up on the sidewall as does the prior art methods. Such an approach does not result in the verticality achieved in the present invention. As the substrate is etched in the prior art methods, polymer buildup on the sidewalls and acts as a mask layer for lower regions of the substrate material to be etched. As the substrate material is etched, more polymer builds up on the sidewalls, acting as an even wider mask for still lower regions of the substrate material to be etched. The result is a square structure that includes a pyramid-like core of substrate material surrounded by triangular-shaped polymer, where the polymer is thickest near the top of the sidewall and thinnest at the base of the sidewall. Once the polymer is removed, the pyramid-like structure of substrate material remains. Such a method does not receive the verticality of the present method and, therefore, results in more lossy optical devices than do devices made by the present invention.

In the present invention, a portion of the substrate is etched (in the preferred embodiment, 2% of the final depth) and then the polymer is removed with a cleaning step. Therefore, there is no polymer mask to cause the etching of the substrate to proceed in a sloped fashion. Instead, the next etch portion proceeds vertically and is followed by another polymer cleaning step. Therefore, the present method results in sidewalls having a verticality of at least 89 degrees, which makes any resulting optical device less lossy than a device made without as many cleaning operations.

What is claimed is:

1. A method of etching a semiconductor material, comprising the steps of:
(a) selecting a substrate of a user-definable semiconductor material;
(b) patterning a mask layer onto the substrate;
(c) etching the substrate material over which the mask layer does not appear for a user-definable time;
(d) removing polymer that built up on the substrate material; and
(e) if step (c) and step (d) were each performed at least twice, then stopping, otherwise returning to step (c) for additional processing.

2. The method claim 1, wherein said step of selecting a substrate of a user-definable semiconductor material is comprised of selecting a substrate made of a Group III-V semiconductor material.

3. The method claim 1, wherein said step of selecting a substrate of a user-definable semiconductor material is comprised of selecting a substrate material made of InP.

4. The method of claim 1, wherein said step of patterning a mask layer onto the substrate is comprised of the steps of:
(a) depositing a mask layer of the substrate selected from the group of mask layers consisting of TiSiO₂, Ti, SiO₂, Si₃N₄, and any other suitable mask;
(b) depositing a resist layer onto the mask layer in a user-definable pattern;
(c) curing the resist layer; and
(d) etching the mask layer.

5. The method of claim 4, wherein said step of depositing a mask layer on the substrate is comprised of the steps of:
(a) depositing 500 nm of SiO₂ onto the substrate material; and
(b) depositing 500 nm of Ti on the SiO₂.

6. The method of claim 1, wherein said step of patterning a mask layer onto the substrate is comprised of the steps of:
(a) depositing resist onto the substrate in a user-definable pattern;
(b) curing the resist pattern;
(c) depositing a mask layer onto the substrate and cured resist pattern, where the mask layer is selected from the group of mask layers consisting of Ni, Cr, NiCr, and any other suitable mask material; and
(d) dissolving the cured resist.

7. The method of claim 1, wherein said step of patterning a mask layer onto the substrate is comprised of the steps of:
(a) depositing a first mask layer onto the substrate;
(b) depositing resist onto the first mask layer in a user-definable pattern;
(c) curing the patterned resist;
(d) depositing a second mask layer onto the cured resist;
(e) dissolving the cured resist; and
(f) etching the first mask layer.

8. The method of claim 7, wherein said step of etching away areas of the mask layer is comprised of the step of etching away areas of the mask layer using RIE and a chemical selected from the group of chemicals consisting of H₂, CH₄, Ar, O₂, CHF₃, SF₆, any suitable combination thereof, and any other suitable chemical.

9. The method of claim 7, wherein said step of etching away areas of the mask layer is comprised of the step of etching away areas of the mask layer using RIE and CH₄—H₂—Ar.

10. The method of claim 1, wherein said step of etching the substrate material over which the mask layer does not appear for a user-definable time is comprised of etching the substrate material over which the mask layer does not appear for a user-definable time using RIE and a chemical selected from the group of chemicals consisting of H₂, CH₄, Ar, O₂, CHF₃, SF₆, any suitable combination thereof, and any other suitable chemical.

11. The method of claim 1, wherein said step of etching the substrate material over which the mask layer does not appear for a user-definable time is comprised of etching the substrate material over which the mask layer does not appear for five minutes using RIE and CH₄—H₂—Ar.

12. The method of claim 1, wherein said step of removing polymer that built up on the substrate material is comprised of removing polymer that built up on the substrate material using a chemical selected from the group of chemicals consisting of hydrofluoric acid, buffered hydrofluoric acid, and O₂.

13. The method of claim 1, wherein said step of removing polymer that built up on the substrate material is comprised of removing polymer that built up on the substrate material for three minutes using a chemical selected from the group of chemicals consisting of HF₄ and O₂.

14. The method of claim 1, wherein said step of stopping if step (c) and step (d) were each performed at least twice is comprised of stopping if step (c) and step (d) were each performed fifty time, otherwise returning to step (c) for additional processing.
